(19) United States
(12) Patent Application Publication
(10) Pub. No.: US 2004/0201109 A1
(43) Pub. Date: Oct. 14, 2004

(54) Semiconductor devices, manufacturing methods therefore, circuit substrates and electronic devices

(75) Inventor: Koji Yamaguchi, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/795,411

(22) Filed: Mar. 9, 2004

(30) Foreign Application Priority Data
Mar. 20, 2003 (JP) 2003-078092

(51) Int. Cl. H01L 23/48

(52) U.S. Cl. 257/777

(57) ABSTRACT

To provide semiconductor devices that are electrically highly reliable, and excellent in mountability, manufacturing methods therefore, circuit substrates and electronic devices, a semiconductor device includes a first semiconductor chip, a second semiconductor chip mounted on the first semiconductor chip, and an electrical connection section that is formed between the first semiconductor chip and the second semiconductor chip and electrically connects the first semiconductor chip and the second semiconductor chip. A plurality of protruded electrodes are formed in an exposed portion on a surface of the first semiconductor chip on which the second semiconductor chip is mounted, which is exposed outside the second semiconductor chip.

### BACKGROUND OF THE INVENTION

1. Field of Invention

The present invention relates to semiconductor devices and manufacturing methods therefore, circuit substrates and electronic devices.

2. Description of Related Art

Semiconductor devices having a plurality of semiconductor chips stacked in layers have been known in the related art. If the semiconductor chips have electrodes in a configuration that can be readily, electrically connected to wires, their mountability to a substrate can be enhanced, and the reliability in electrical connection of semiconductor devices can be enhanced.

### SUMMARY OF THE INVENTION

The present invention provides semiconductor devices that are electrically highly reliable and excellent in mountability, manufacturing methods therefore, circuit substrates and electronic devices.

A semiconductor device in accordance with an aspect of the present invention, includes: a first semiconductor chip; a second semiconductor chip mounted on the first semiconductor chip; and an electrical connection section that is formed between the first semiconductor chip and the second semiconductor chip and electrically connects the first semiconductor chip and the second semiconductor chip, a plurality of protruded electrodes formed on an exposed portion of a surface of the first semiconductor chip on which the second semiconductor chip is mounted and which is exposed outside the second semiconductor chip.

In accordance with an aspect of the present invention, the protruded electrodes are formed in a portion of the first semiconductor chip which is exposed outside the second semiconductor chip. Consequently, it can be readily mounted on a circuit substrate, and a semiconductor device that is highly reliable in its electrical connection can be provided.

A semiconductor device in accordance with an aspect of the present invention includes: a first semiconductor chip; a second semiconductor chip mounted on the first semiconductor chip; an electrical connection section that is formed between the first semiconductor chip and the second semiconductor chip and electrically connects the first semiconductor chip and the second semiconductor chip; a substrate having a wiring pattern; and wires, a plurality of protruded electrodes formed on an exposed portion of a surface of the first semiconductor chip on which the second semiconductor chip is mounted and which is exposed outside the second semiconductor chip, the first and second semiconductor chips are mounted on the substrate, and the wiring pattern and the protruded electrodes are electrically connected to the wires.

In accordance with an aspect of the present invention, the protruded electrodes are formed in a portion of the first semiconductor chip which is exposed outside the second semiconductor chip. Consequently, the semiconductor chips and the wiring can be readily, electrically connected to the wires and a semiconductor device that is highly reliable in its electrical connection can be provided.

In the semiconductor device, the substrate includes a concave section, and at least a part of the first semiconductor chip may be disposed inside the concave section.

Consequently, the thickness of the semiconductor device can be reduced, and a semiconductor device that is excellent in its mountability can be provided.

In the semiconductor device, the first semiconductor chip has a surface that faces the second semiconductor chip and an opposite surface that may be in contact with a bottom surface of the concave section.

In the semiconductor device, the substrate may include a heat radiating section, and the first semiconductor chip may be in contact with the heat radiating section.

A semiconductor device in accordance with an aspect of the present invention includes: a first semiconductor chip; a second semiconductor chip mounted on the first semiconductor chip; an electrical connection section that is formed between the first semiconductor chip and the second semiconductor chip and electrically connects the first semiconductor chip and the second semiconductor chip; and a substrate having a wiring pattern; a plurality of protruded electrodes formed on an exposed portion of a surface of the first semiconductor chip on which the second semiconductor chip is mounted and which is exposed outside the second semiconductor chip, and the protruded electrodes are opposed to and electrically connected to the wiring pattern.

In accordance with an aspect of the present invention, the protruded electrodes are formed in a portion of the first semiconductor chip which is exposed outside the second semiconductor chip. Consequently, the semiconductor chips and the wiring can be readily, electrically connected to one another, and a semiconductor device that is highly reliable in its electrical connection can be provided.

In the semiconductor device, the substrate may include a concave section and an opening formed in a bottom surface of the concave section, at least a part of the first semiconductor chip may be disposed inside the concave section, and at least a part of the second semiconductor chip may be disposed inside the opening.

Consequently, the thickness of the semiconductor device can be reduced, and a semiconductor device that is excellent in its mountability can be provided.

In the semiconductor device, the first semiconductor chip may have an outer configuration that is larger than an outer configuration of the second semiconductor chip.

A circuit substrate in accordance with an aspect of the present invention may have the semiconductor device described above mounted thereon.

An electronic device in accordance with an aspect of the present invention may have the semiconductor device described above.

A method to manufacture a semiconductor device in accordance with an aspect of the present invention includes: forming first protruded electrodes and second protruded electrodes on a first semiconductor chip; forming third protruded electrodes on a second semiconductor chip; and mounting the second semiconductor chip in a region of the first semiconductor chip where the first protruded electrodes are formed, and electrically connecting the first protruded electrodes and the third protruded electrodes which are opposed to one another.

In accordance with an aspect of the present invention, the second protruded electrodes are formed in a portion of the first semiconductor chip which is exposed outside the second semiconductor chip. Consequently, a semiconductor device that is readily mounted on a circuit substrate and is highly reliable in its electrical connection can be manufactured.

A method to manufacture a semiconductor device in accordance with an aspect of the present invention includes: (a) forming first protruded electrodes and second protruded electrodes on a first semiconductor chip; (b) forming third protruded electrodes on a second semiconductor chip; (c) mounting the second semiconductor chip in a region of the first semiconductor chip where the first protruded electrodes are formed, and electrically connecting the first protruded electrodes and the third protruded electrodes which are opposed to one another; (d) mounting the first semiconductor chip and the second semiconductor chip on a substrate having a wiring pattern; and (e) electrically connecting the second protruded electrodes and the wiring pattern with wires.

In accordance with an aspect of the present invention, the second protruded electrodes are formed in a portion of the first semiconductor chip which is exposed outside the second semiconductor chip. Consequently, the semiconductor chips and the wiring can be readily, electrically connected to the wires, such that a semiconductor device that is highly reliable in its electrical connection can be manufactured.

In the method to manufacture a semiconductor device, in (e), after bonding a part of the wires to the wiring pattern, another part of the wires may be bonded to the second protruded electrodes.

Consequently, loops of the wires can be made lower such that a semiconductor device that is thin and excellent in its mountability can be manufactured.

In the method to manufacture a semiconductor device, the substrate may include a concave section; and in (d), at least a part of the first semiconductor chip may be disposed inside the concave section. Consequently, a semiconductor device that is thin and excellent in its mountability can be manufactured.

In the method to manufacture a semiconductor device, in (d), an opposite side surface of a surface of the first semiconductor chip that faces the second semiconductor chip may be brought in contact with a bottom surface of the concave section.

In the method to manufacture a semiconductor device, the substrate may have a heat radiating section, and in (d), the first semiconductor chip may be brought in contact with the heat radiating section.

A method to manufacture a semiconductor device in accordance with an aspect of the present invention, includes: (a) forming first protruded electrodes and second protruded electrodes on a first semiconductor chip; (b) forming third protruded electrodes on a second semiconductor chip; (c) mounting the second semiconductor chip in a region of the first semiconductor chip where the first protruded electrodes are formed, and electrically connecting the first protruded electrodes and the third protruded electrodes which are opposed to one another; and (d) electrically connecting the second protruded electrodes and a wiring pattern formed on a substrate which are opposed to one another.

In accordance with an aspect of the present invention, the second protruded electrodes are formed in a portion of the first semiconductor chip which is exposed outside the second semiconductor chip. Consequently, the semiconductor chips and the wiring can be opposed and readily, electrically connected to one another, such that a semiconductor device that is highly reliable in its electrical connection can be manufactured.

In the method to manufacture a semiconductor device, the substrate may include a concave section and an opening formed in a bottom surface of the concave section; and in (d), at least a part of the first semiconductor chip may be disposed inside the concave section, and at least a part of the second semiconductor chip may be disposed inside the opening.

Consequently, a semiconductor device that is thin and excellent in its mountability can be manufactured.

In the method to manufacture a semiconductor device, in (a), the first protruded electrodes and the second protruded electrodes may be formed to be generally in the same height.

In the method to manufacture a semiconductor device, in (a), the first protruded electrodes and the second protruded electrodes may be collectively formed.

In the method to manufacture a semiconductor device, in (a), a height difference between the first protruded electrodes and the second protruded electrodes may be made to be within 5 μm.

In the method to manufacture a semiconductor device, in (a), the first protruded electrodes may be formed to be higher than the second protruded electrodes.

In the method to manufacture a semiconductor device, the first protruded electrodes may include a first metal layer and a second metal layer formed on the first metal layer, the second protruded electrodes may include a third metal layer and a fourth metal layer formed on the third metal layer, the first metal layer and the third metal layer may be formed with the same compositions and the second metal layer and the fourth metal layer may be formed with the same compositions.

The method to manufacture a semiconductor device may further include forming another metal layer on the second metal layer.

In the method to manufacture a semiconductor device, before (c), electrical characteristics of the first semiconductor chip may be examined. Accordingly, the electrical characteristics of the first semiconductor chip are examined before the second semiconductor chip is mounted on the first semiconductor chip. Specifically, the first semiconductor chip has the first and second protruded electrodes at the time of the examination. In this instance, if the first and second protruded electrodes are formed to have generally the same height, or a height difference between them being less than 5 μm, the first semiconductor chip can be readily examined, such that a highly reliable semiconductor device can be manufactured.

In the method to manufacture a semiconductor device, the first semiconductor chip may have an outer configuration larger than an outer configuration of the second semiconductor chip.

### BRIEF DESCRIPTION OF THE DRAWINGS

FIG. 1 is a schematic showing a method to manufacture a semiconductor device in accordance with a first exemplary embodiment of the present invention;

FIG. 2 is a schematic showing the method to manufacture a semiconductor device in accordance with the first exemplary embodiment of the present invention;

FIG. 3 is a schematic showing the method to manufacture a semiconductor device in accordance with the first exemplary embodiment of the present invention;

FIG. 4 is a schematic showing the method to manufacture a semiconductor device in accordance with the first exemplary embodiment of the present invention;

FIG. 5 is a schematic showing the method to manufacture a semiconductor device in accordance with the first exemplary embodiment of the present invention;

FIG. 6 is a schematic showing the method to manufacture a semiconductor device in accordance with the first exemplary embodiment of the present invention;

FIG. 7 is a schematic showing the method to manufacture a semiconductor device in accordance with the first exemplary embodiment of the present invention;

FIG. 8 is a schematic showing the method to manufacture a semiconductor device in accordance with the first exemplary embodiment of the present invention;

FIG. 9 is a schematic showing the method to manufacture a semiconductor device in accordance with the first exemplary embodiment of the present invention;

FIG. 10 is a schematic showing a method to manufacture a semiconductor device in accordance with a second exemplary embodiment of the present invention;

FIG. 11 is a schematic showing a circuit substrate having a semiconductor device in accordance with an exemplary embodiment of the present invention mounted thereon;

FIG. 12 is a schematic showing an electronic device having a semiconductor device in accordance with an exemplary embodiment of the present invention;

FIG. 13 is a schematic showing an electronic device having a semiconductor device in accordance with an exemplary embodiment of the present invention; and

FIG. 14 is a schematic showing a method to manufacture a semiconductor device in accordance with a third exemplary embodiment of the present invention.

### DETAILED DESCRIPTION OF PREFERRED EMBODIMENTS

Exemplary embodiments of the present invention are described below with reference to the accompanying drawings. However, the present invention is not limited to the exemplary embodiments described below.

First Exemplary Embodiment

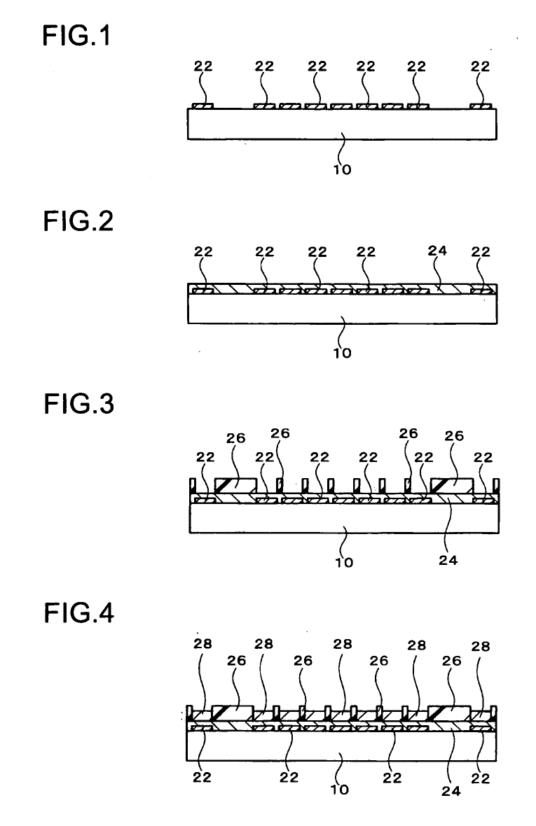

FIG. 1-FIG. 9 are views to describe a method to manufacture a semiconductor device in accordance with a first exemplary embodiment of the present invention.

First, a first semiconductor chip 10 is prepared. The first semiconductor chip 10 may be prepared in the state of a wafer, and steps to be described below may be conducted. The semiconductor chip 10 may include an integrated circuit. The plane configuration of the semiconductor chip 10 may generally be a rectangular, but is not particularly limited. The first semiconductor chip 10 may include pads 22 (see FIG. 1). The pads 22 may be formed with Al, for example. The pads 22 may be formed on one surface of the first semiconductor chip 10 in a plurality of rows and a plurality of columns.

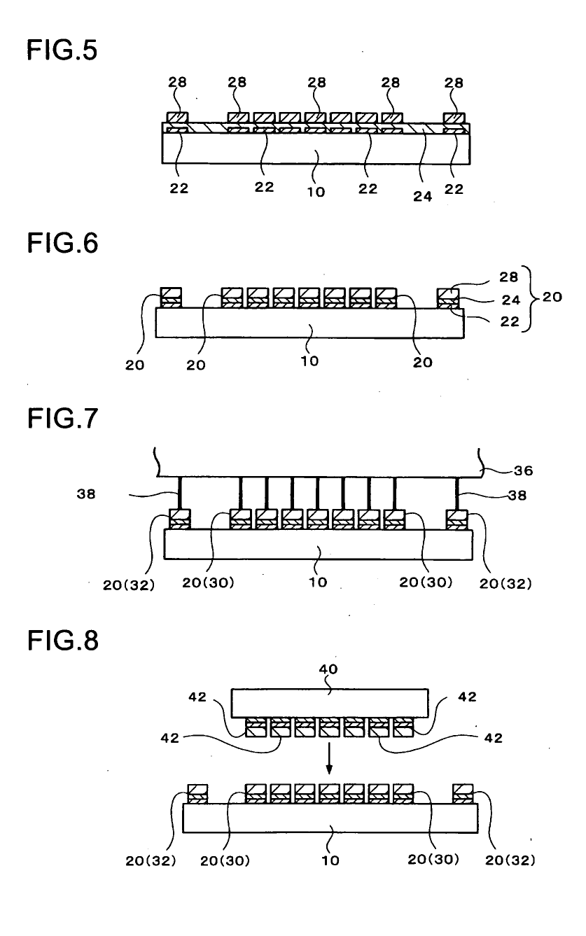

Next, a plurality of protruded electrodes 20 are formed on the first semiconductor chip 10. First, a seed layer 24 is formed on the first semiconductor chip 10 having the pads 22. As indicated in FIG. 2, the seed layer 24 may be provided over the entire surface of the first semiconductor chip 10 where the pads 22 are formed. The seed layer 24 may be formed from, for example Ti, TiN, or TiW. Next, a resist 26 is formed on the seed layer 24 (see FIG. 3). The resist 26 may be formed without overlapping the pads 22. The resist 26 may be formed by patterning a flat resist layer formed on the seed layer 24 in a manner to remove relevant parts thereof. By patterning, resist layers in regions that overlap the pads 22 may be removed. The resist layers may be patterned through exposing and developing. Alternatively, the resist 26 may be formed in a manner to avoid regions that overlap the pads 22. Next, metal layers 28 are formed on portions that are exposed through the resist 26 (i.e., portions that overlap the pads 22) on the seed layer 24 (see FIG. 4). The metal layers 28 may be formed by electroplating. By forming the seed layer 24 over the entire surface of the first semiconductor chip 10, a plurality of the metal layers 28 can be collectively formed. The metal layers 28 may be formed from a single metal layer, or a plurality of metal layers may be stacked in layers to form the metal layers 28. Next, the resist 26 is removed (see FIG. 5). Last, the seed layer 24 in portions that are exposed through the metal layers 28 may be removed, such that a plurality of protruded electrodes 20 are formed (see FIG. 6). By using the metal layers 28 as a mask, relevant portions of the seed layer 24 may be removed. It is noted that third protruded electrodes 42 may be formed on a second semiconductor chip 40 through steps similar to the above steps.

The protruded electrodes 20 formed on the first semiconductor chip 10 include first protruded electrodes 30 and second protruded electrodes 32. In a later step (a step in which the second semiconductor chip 40 is mounted on the first semiconductor chip 10), the protruded electrodes 20 formed in a region that overlaps the second semiconductor chip 40 may be defined as the first protruded electrodes 30, and the protruded electrodes 20 formed in a region that is exposed outside the second semiconductor chip 40 (exposed portion 14) may be defined as the second protruded electrodes 32. For example, the first protruded electrodes 30 may be disposed near the center of the first semiconductor chip 10, and the second protruded electrodes 32 may be disposed near a circumference section of the first semiconductor chip 10 in a manner to encircle the first protruded electrodes 30. The first protruded electrodes 30 and the second protruded electrodes 32 may be formed to have generally the same height. Alternatively, the first protruded electrodes 30 and the second protruded electrodes 32 may be formed such that a height difference between them is within 5 μm. Also, as described above, the first and second protruded electrodes 30 and 32 may be collectively formed.

As described above, the metal layer 28 may be formed with a single layer, or a plurality of metal layers stacked in layers. When the metal layer 28 is formed with a plurality of metal layers stacked in layers, the protruded electrodes 30 each may be formed to have a first metal layer formed on the seed layer 24 and a second metal layer formed on the first metal layer. Also, the second protruded electrodes 32 each may be formed to have a third metal layer formed on the seed layer 24 and a fourth metal layer formed on the third metal layer. In this case, the first metal layer and the third metal layer may be formed with the same composition, and the second metal layer and the fourth metal layer may be formed with the same composition. By forming the respective layers with the same compositions, the protruded electrodes 20 can be collectively formed, such that a semiconductor device can be effectively manufactured. For example, the first and third metal layers may be formed with nickel (Ni), and the second and fourth metal layers may be formed with gold (Au). It is noted that another metal layer (not shown) (for example, solder) may be formed on the second metal layer. In this instance, the protruded electrodes 20 may be formed in a manner that the first protruded electrodes 30 become higher than the second protruded electrodes 32. It is noted that the other metal layer may be formed such that the height of the other metal layer is within 5 μm. By so doing, the first protruded electrodes 30 and the third protruded electrodes 42 can be readily bonded together.

Next, electrical characteristics of the first and second semiconductor chips 10 and 40 may be examined. This examination may be conducted before the second semiconductor chip 40 is mounted on the first semiconductor chip 10. Also, the examination may be conducted after the protruded electrodes are formed on the first and second semiconductor chips 10 and 40. By so doing, a semiconductor device that is highly reliable in its electrical connection can be manufactured. FIG. 7 is a view indicating the examination. In the examination, multiple fine needles 38 formed on an examination jig 36 are brought in contact with the protruded electrodes 20, to thereby examine its electrical characteristics. By forming the first protruded electrodes 30 and the second protruded electrodes 32 to have generally the same height, or a height difference between them to be within 5 μm, all the protruded electrodes 20 can be contacted with the needles 38, such that a highly reliable examination can be conducted. Therefore a highly reliable semiconductor device can be manufactured.

Next, the second semiconductor chip 40 is mounted in a region of the first semiconductor chip 10 in which the first protruded electrodes 30 are formed, and the first protruded electrodes 30 and the third protruded electrodes 42 are opposed and electrically connected to one another (see FIG. 8). For example, the first and second semiconductor chips 10 and 40 are positioned with each other such that the first protruded electrodes 30 and the second protruded electrodes 42 are opposed to one another. In this instance, the second protruded electrodes 32 may be exposed out of the second semiconductor chip 40. Then, the first protruded electrodes 30 and the third protruded electrodes 42 are brought in contact with one another, and the first protruded electrodes 30 and the third protruded electrodes 42 may be electrically connected by metal bonding under application of heat and pressure. Alternatively, by using an ACF (anisotropic conductive film) or ACP (anisotropic conductive paste), conductive particles may be provided between the first protruded electrodes 30 and the third protruded electrodes 42 to thereby electrically connect the first protruded electrodes 30 and the third protruded electrodes 42. It is noted that the outer configuration of the first semiconductor chip 10 may be larger than the outer configuration of the second semiconductor chip 40.

By the method to manufacture a semiconductor device in accordance with the present exemplary embodiment, the protruded electrodes 20 (more specifically, the second protruded electrodes 32) are formed in a portion of the first semiconductor chip 10 (exposed section 14), which is exposed outside the second semiconductor chip 40. By this, electrical connections of the protruded electrodes 20 can be readily made, such that a semiconductor device that is highly reliable in electrical connection and excellent in mountability can be manufactured.

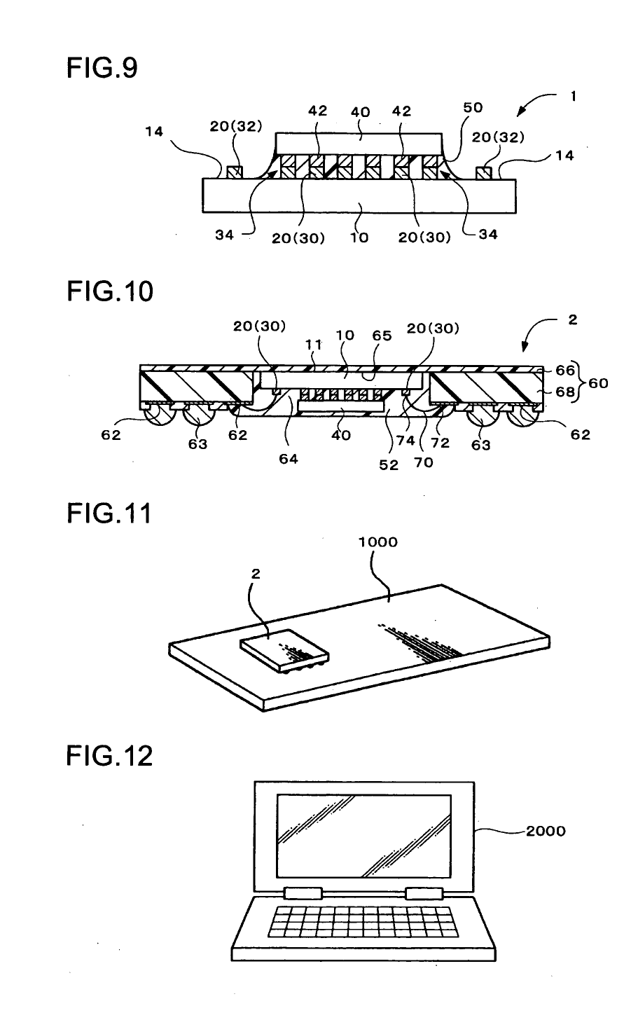

By the steps described above, a semiconductor device 1 can be manufactured. It is noted that FIG. 9 shows a cross-sectional view of the semiconductor device 1. The semiconductor device 1 includes a first semiconductor chip 10, a second semiconductor chip 40 mounted on the first semiconductor chip 10, and an electrical connection section 34 formed between the first semiconductor chip 10 and the second semiconductor chip 40. The electrical connection section 34 plays a role of electrically connecting the first and second semiconductor chips 10 and 40. The electrical connection section 34 may be formed with a plurality of metal layers stacked in layers. More specifically, in the electrical connection section 34, the first protruded electrodes 30 and the third protruded electrodes 42 may be bonded together, or may be electrically connected through conductive particles.

The semiconductor device 1 includes a plurality of protruded electrodes 20, the protruded electrodes 20 are formed on a surface of the first semiconductor chip 10 on which the second semiconductor chip 40 is mounted in a portion thereof that is exposed outside the second semiconductor chip 40 (exposed portion 14). In other words, second protruded electrodes 32 on the first semiconductor chip 10 may be referred to as the protruded electrodes 20. Accordingly, since the protruded electrodes 20 are disposed in the exposed portion 14 of the first semiconductor chip 10, the protruded electrodes 20 can be readily, electrically connected to a wiring substrate or the like. In other words, a semiconductor device that readily allows electrical connection and is excellent in mountability can be provided. It is noted that, as indicated in FIG. 9, the semiconductor device 1 may include a resin layer 50. With this layer, stresses generated in each of the electrical connection sections 34 can be alleviated, such that a semiconductor device that is highly reliable against stresses can be provided.

It is noted that semiconductor devices in accordance with the present exemplary embodiment include any compositions that may derive from any of the specific items selected from the above described manufacturing methods, and the semiconductor devices in accordance with the present exemplary embodiment are equipped with the effects described above.

Second Exemplary Embodiment

A method to manufacture a semiconductor device in accordance with a second exemplary embodiment of the present invention is described below. The contents described above may be applied to the present exemplary embodiment as long as they are applicable.

The method to manufacture a semiconductor device in accordance with the present exemplary embodiment includes mounting first and second semiconductor chips 10 and 40 on a substrate 60. The substrate 60 includes a wiring pattern 62. The contents already described above can be applied to the first and second semiconductor chips 10 and 40. Also, the first and second semiconductor chips 10 and 40 may be composed as a semiconductor device 1.

The material of the substrate 60 is not particularly limited. The substrate 60 may be formed with either organic material or inorganic material, or may be composed of a compound structure using these materials. As an organic substrate, for example, a substrate composed of polyethylene terephthalate (PET) may be used. Also, as a substrate 60 that is formed with inorganic material, for example, a ceramics substrate or a glass substrate can be used. As a compound structure using organic and inorganic materials, a glass epoxy substrate may be listed. Also, the substrate 60 may be formed from two or more parts composed of different materials. For example, a member having a higher heat radiation property than the first or second semiconductor chip 10 or 40 may be used in a part of the substrate 60, the substrate 60 having a heat radiating section can be formed. In this case, the first semiconductor chip 10 may be contacted with the heat radiating section. Also, the configuration of the substrate 60 is not particularly limited. For example the substrate 60 may have a concave section 64. On a first substrate 66, a second substrate 68 having an opening may be mounted, to thereby form the substrate 60 having the concave section 64. In other words, the substrate 60 may be formed from the first substrate 66 and the second substrate 68. In this instance, the first substrate 66 may be composed of a member having a higher heat radiating property than the first or second semiconductor chip 10 or 40.

The substrate 60 includes a wiring pattern 62. The wiring pattern 62 can be formed through, for example, adhering a metal foil, such as a copper foil to the substrate 60 through adhesive, conducting photolithography and then conducting etching. Or, sputtering may be conducted to form the wiring pattern 62. Alternatively, the wiring pattern 62 may be formed by using an additive method in which the wiring pattern 62 is formed by electroless plating. When the substrate 60 is formed from the first substrate 66 and the second substrate 68, the wiring pattern 62 may be formed on the second substrate 68.

Next, second protruded electrodes 32 that are formed in a portion (exposed portion 14) of the first semiconductor chip 10 which is exposed outside the second semiconductor chip 40 and the wiring pattern 62 are electrically connected to wires 70. The wires 70 may be formed by any one of the bonding tools that are suitable. Also, any suitable wires can be used as the wires 70. By the method to manufacture a semiconductor device in accordance with the present exemplary embodiment of the invention, the second protruded electrodes 34 are formed in the exposed portion 14. Accordingly, the wires 70 can be readily bonded to the second protruded electrodes 34. Therefore a semiconductor device that is highly reliable in its electrical connection can be manufactured. It is noted that, since the first semiconductor chip 10 has the protruded electrodes 20, the first semiconductor chip 10 is reduced or prevented from being damaged even when a so-called second bonding is conducted on the side of the first semiconductor chip 10. Therefore, one part 72 of the wires 70 are bonded to the wiring pattern 62, and thereafter, the other parts 74 of the wires 70 are bonded to the second protruded electrodes 34, whereby the wires 70 can be formed. As a result, the loop height of the wires 70 can be lowered, such that a semiconductor device that is thin and excellent in mountability can be manufactured.

When the substrate 60 includes a concave section 64, the first and second semiconductor chips 10 and 40 (semiconductor device 1) may be mounted on the substrate 60 in a manner that at least a part of the first semiconductor chip 10 is disposed inside the concave section 64. Consequently, the thickness of the semiconductor device can be made thinner, such that a semiconductor device that further excels in mountability can be manufactured. Also, the first and second semiconductor chips 10 and 40 may be mounted such that a surface 11 of the first semiconductor chip 10, which is opposite to a surface thereof that faces the second semiconductor chip 40, is in contact with a bottom surface 65 (i.e., the first substrate 66) of the concave section 64. Also, when the substrate 60 has a heat radiating section, the first and second semiconductor chips 10 and 40 may be mounted such that the surface 11 of the first semiconductor chip 10 is in contact with the heat radiating section. Consequently, a highly reliable semiconductor device having excellent heat radiating property can be manufactured. The first substrate 66 may be formed with a member having high heat radiation property, and the surface 11 of the first semiconductor chip 10 may be placed in contact with the bottom surface 65 of the concave section 64.

Finally, external terminals 63 may be formed. The external terminals 63 are formed such that they can be electrically connected to the wiring pattern 62. The external terminals 63 may be formed with solder, for example.

By the steps described above, a semiconductor device 2 can be manufactured. FIG. 10 shows a cross-sectional view of the semiconductor device 2. The semiconductor device 2 includes a first semiconductor chip 10, a second semiconductor chip 40 mounted on the first semiconductor chip 10, and an electrical connection section 34 formed between the first semiconductor chip 10 and the second semiconductor chip 40. The electrical connection section 34 plays a role of electrically connecting the first and second semiconductor chips 10 and 40. Further, a plurality of protruded electrodes 20 (second protruded electrodes 32) are formed in an exposed portion 14 of the first semiconductor chip 10. In other words, the semiconductor device 2 of the present exemplary embodiment includes the semiconductor device 1 described above.

The semiconductor device 2 includes a substrate 60. The substrate 60 has a wiring pattern 62 formed thereon. The first semiconductor chip 10 and the second semiconductor chip 40 are mounted on the substrate 60. In other words, the semiconductor device 1 described above is mounted on the substrate 60. The substrate 60 may have a concave section 64. In this case, at least a part of the first semiconductor chip 10 may be disposed inside the concave section 64. Consequently, a semiconductor device that is thin and has excellent mountability can be provided.

The semiconductor device 2 includes wires 70. The wiring pattern 62 and the protruded electrodes 20 of the first semiconductor chip 10 are electrically connected to the wires 70. As described above, the protruded electrodes 20 are formed in the exposed portion 14 of the semiconductor chip 10 that composes the semiconductor device 1. Accordingly, a semiconductor device that has stable connections between the wires 70 and the protruded electrodes 20 (second protruded electrodes 32) and is highly reliable in electrical connection can be provided.

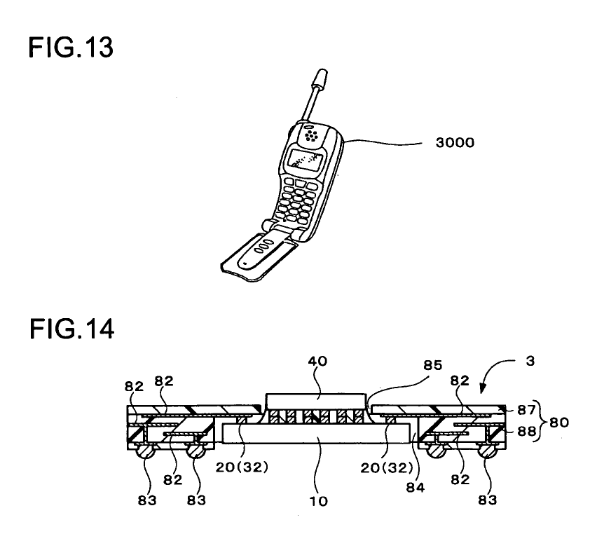

The semiconductor device 2 may include a resin layer 52. The wires 72 can be protected by this, and therefore a highly reliable semiconductor device can be provided. FIG. 11 shows a circuit substrate 1000 on which the semiconductor device 2 described above is mounted. Also, as electronic devices each having the semiconductor device 2, a notebook type personal computer 2000 is shown in FIG. 12, and a portable telephone 3000 is shown in FIG. 13.

Third Exemplary Embodiment

A method to manufacture a semiconductor device in accordance with a third exemplary embodiment of the present invention is described below. The contents described above can also be applied to the present exemplary embodiment as long as they are applicable.

The method to manufacture a semiconductor device in accordance with the present exemplary embodiment includes mounting first and second semiconductor chips 10 and 40 on a substrate 80. The substrate 80 includes a wiring pattern 82 formed thereon. Also, the first and second semiconductor chips 10 and 40 may be composed as a semiconductor device 1.

The material of the substrate 80 is not particularly limited, and the contents of the substrate 60 described above may be applicable. Also, the configuration of the substrate is not particularly limited. However, the substrate 80 may include a concave section 84, and an opening 85 may be formed in a bottom surface of the concave section 84. Through mounting a second substrate 88 having an opening on a first substrate 87 having an opening 85, the substrate 80 having the concave section 84 and the opening 85 may be formed. The second substrate 88 may have a wiring pattern 82 formed in multiple layers, as indicated in FIG. 14.

In the method to manufacture a semiconductor device in accordance with the present exemplary embodiment, the second protruded electrodes 32 and the wiring pattern 82 formed on the substrate 80 are opposed to one another and electrically connected. For example, the second protruded electrodes 32 and the wiring pattern 82 are brought in contact with one another, and the second protruded electrodes 32 and the wiring pattern 82 may be electrically connected by metal bonding under application of heat and pressure. Alternatively, by using an ACF (anisotropic conductive film) or ACP (anisotropic conductive paste), conductive particles (not shown) may be provided between the second protruded electrodes 32 and the wiring pattern 82 to thereby electrically connect the second protruded electrodes 33 and the wiring pattern 82.

By the method to manufacture a semiconductor device in accordance with the present exemplary embodiment, the protruded electrodes 20 (the second protruded electrodes 32) are opposed to the wiring pattern 82, and they are electrically connected. The second protruded electrodes 32 can be readily placed facing to the wiring pattern 82 because they are formed in the exposed portion 14 of the first semiconductor chip 10, such that a semiconductor device that is highly reliable in electrical connection can be manufactured.

It is noted that, when the substrate 80 includes the concave section 84, and the opening 85 formed in the bottom surface of the concave section 84, the semiconductor device 1 may be mounted such that at least a part of the first semiconductor chip 10 is disposed inside the concave section 84, and at least a part of the second semiconductor chip 40 is disposed inside the opening 85. Accordingly, a semiconductor device that is thin and excels in mountability can be manufactured.

Finally, external terminals 83 may be formed. The external terminals 83 are formed such that they can be electrically connected to the wiring pattern 82. The external terminals 83 may be formed with solder, for example.

By the steps described above, a semiconductor device 3 can be manufactured. FIG. 14 shows a cross-sectional view of the semiconductor device 3. The semiconductor device 3 includes a first semiconductor chip 10, a second semiconductor chip 40 mounted on the first semiconductor chip 10, and an electrical connection section 34 formed between the first semiconductor chip 10 and the second semiconductor chip 40. The electrical connection section 34 plays a role of electrically connecting the first and second semiconductor chips 10 and 40. Further, a plurality of protruded electrodes 20 (second protruded electrodes 32) are formed in an exposed portion 14 of the first semiconductor chip 10. In other words, the semiconductor device 3 of the present exemplary embodiment includes the semiconductor device 1 described above.

The semiconductor device 3 includes a substrate 80. The substrate 80 has a wiring pattern 82 formed thereon. Then, the protruded electrodes 20 (second protruded electrodes 34) of the first semiconductor chip 10 are opposed to the wiring pattern 82 and electrically connected to each other. As described above, the protruded electrodes 20 (second protruded electrodes 34) are formed in the exposed portion 14 of the first semiconductor chip 10 that composes the semiconductor device 1. Accordingly, a highly reliable semiconductor device that has stable connections between the protruded electrodes 20 (second protruded electrodes 32) and the wiring pattern 82 can be provided. It is noted that the substrate 80 may include a concave section 84, and an opening 85 that is formed in the bottom surface of the concave section 84. In this case, at least a part of the semiconductor chip 10 may be disposed inside the concave section 84, and at least a part of the second semiconductor chip 40 may be disposed inside the opening 85. Consequently, a semiconductor device that is thin and excels in mountability can be provided.

The present invention is not limited to the exemplary embodiments described above, and many modification can be made. For example, the present invention may include compositions that are substantially the same as the compositions described in the exemplary embodiments (for example, a composition that has the same functions, the same methods and the results, or a composition that has the same objects and results). Also, the present invention may include compositions in which portions not essential in the compositions described in the exemplary embodiments are replaced with others. Also, the present invention may include compositions that achieve the same functions and effects as those of the compositions described in the exemplary embodiments. Furthermore, the present invention may include compositions that include known technology added to the compositions described in the exemplary embodiments.

What is claimed is:

1. A semiconductor device, comprising:
a first semiconductor chip;
a second semiconductor chip mounted on the first semiconductor chip; and
an electrical connection section that is formed between the first semiconductor chip and the second semiconductor chip and electrically connects the first semiconductor chip and the second semiconductor chip,
a plurality of protruded electrodes formed in an exposed portion on a surface of the first semiconductor chip on which the second semiconductor chip is mounted, which is exposed outside the second semiconductor chip.

2. A semiconductor device, comprising:
a first semiconductor chip;
a second semiconductor chip mounted on the first semiconductor chip;
an electrical connection section that is formed between the first semiconductor chip and the second semiconductor chip and electrically connects the first semiconductor chip and the second semiconductor chip;
a substrate having a wiring pattern; and
wires,
a plurality of protruded electrodes formed in an exposed portion on a surface of the first semiconductor chip on which the second semiconductor chip is mounted, which is exposed outside the second semiconductor chip,
the first and second semiconductor chips mounted on the substrate, and
the wiring pattern and the protruded electrodes electrically connected to the wires.

3. The semiconductor device according to claim 2, the substrate including a concave section, and at least a part of the first semiconductor chip disposed inside the concave section.

4. The semiconductor device according to claim 3, the first semiconductor chip having a surface that faces the second semiconductor chip and a surface on the opposite side thereof that is in contact with a bottom surface of the concave section.

5. The semiconductor device according to claim 2, the substrate including a heat radiating section, and the first semiconductor chip being in contact with the heat radiating section.

6. A semiconductor device, comprising:
a first semiconductor chip;
a second semiconductor chip mounted on the first semiconductor chip;
an electrical connection section that is formed between the first semiconductor chip and the second semiconductor chip and electrically connects the first semiconductor chip and the second semiconductor chip; and
a substrate having a wiring pattern;
a plurality of protruded electrodes formed in an exposed portion on a surface of the first semiconductor chip on which the second semiconductor chip is mounted, which is exposed outside the second semiconductor chip, and
the protruded electrodes opposed and electrically connected to the wiring pattern.

7. The semiconductor device according to claim 6,
the substrate including a concave section and an opening formed in a bottom surface of the concave section,
at least a part of the first semiconductor chip disposed inside the concave section, and
at least a part of the second semiconductor chip disposed inside the opening.

8. The semiconductor device according to claim 1, the first semiconductor chip having an outer configuration that is larger than an outer configuration of the second semiconductor chip.

9. A circuit substrate having a semiconductor device according to claim 1 mounted thereon.

10. An electronic device having a semiconductor device according to claim 1.

11. A method to manufacture a semiconductor device, comprising:
(a) forming first protruded electrodes and second protruded electrodes on a first semiconductor chip;
(b) forming third protruded electrodes on a second semiconductor chip; and
(c) mounting the second semiconductor chip in a region of the first semiconductor chip where the first protruded electrodes are formed, and electrically connecting the first protruded electrodes and the third protruded electrodes which are opposed to one another.

12. A method to manufacture a semiconductor device, comprising:
(a) forming first protruded electrodes and second protruded electrodes on a first semiconductor chip;
(b) forming third protruded electrodes on a second semiconductor chip;
(c) mounting the second semiconductor chip in a region of the first semiconductor chip where the first protruded electrodes are formed, and electrically connecting the first protruded electrodes and the third protruded electrodes which are opposed to one another;
(d) mounting the first semiconductor chip and the second semiconductor chip on a substrate having a wiring pattern; and
(e) electrically connecting the second protruded electrodes and the wiring pattern with wires.

13. The method to manufacture a semiconductor device according to claim 12, in (e), after bonding a part of the wires to the wiring pattern, another part of the wires being bonded to the second protruded electrodes.

14. The method to manufacture a semiconductor device according to claim 12, the substrate including a concave section; and (d), at least a part of the first semiconductor chip disposed inside the concave section.

15. The method to manufacture a semiconductor device according to claim 14, in (d), an opposite side surface of a surface of the first semiconductor chip that faces the second semiconductor chip being brought in contact with a bottom surface of the concave section.

16. The method to manufacture a semiconductor device according to claim 12, the substrate having a heat radiating section, and in (d), the first semiconductor chip being brought in contact with the heat radiating section.

17. A method to manufacture a semiconductor device, comprising:
(a) forming first protruded electrodes and second protruded electrodes on a first semiconductor chip;
(b) forming third protruded electrodes on a second semiconductor chip;
(c) mounting the second semiconductor chip in a region of the first semiconductor chip where the first protruded electrodes are formed, and electrically connecting the first protruded electrodes and the third protruded electrodes which are opposed to one another; and
(d) electrically connecting the second protruded electrodes and a wiring pattern formed on a substrate which are opposed to one another.

18. The method to manufacture a semiconductor device according to claim 17,
the substrate including a concave section and an opening formed in a bottom surface of the concave section; and
in (d), at least a part of the first semiconductor chip disposed inside the concave section, and at least a part of the second semiconductor chip disposed inside the opening.

19. The method to manufacture a semiconductor device according to claim 1 1, in (a), the first protruded electrodes and the second protruded electrodes formed to be generally identical in height.

20. The method to manufacture a semiconductor device according to claim 19, in (a), the first protruded electrodes and the second protruded electrodes collectively formed.

21. The method to manufacture a semiconductor device according to claim 11, in (a), a height difference between the first protruded electrodes and the second protruded electrodes being made to be within 5 μm.

22. The method to manufacture a semiconductor device according to claim 21, in (a), the first protruded electrodes formed to be higher than the second protruded electrodes.

23. The method to manufacture a semiconductor device according to claim 11,
the first protruded electrodes including a first metal layer and a second metal layer formed on the first metal layer,
the second protruded electrodes including a third metal layer and a fourth metal layer formed on the third metal layer,
the first metal layer and the third metal layer formed with identical compositions, and
the second metal layer and the fourth metal layer formed with identical compositions.

24. The method to manufacture a semiconductor device according to claim 22, further comprising:
the first protruded electrodes including a first metal layer and a second metal layer formed on the first metal layer,
the second protruded electrodes including a third metal layer and a fourth metal layer formed on the third metal layer,
the first metal layer and the third metal layer formed with identical compositions,
the second metal layer and the fourth metal layer formed with identical compositions, and
forming another metal layer on the second metal layer.

25. The method to manufacture a semiconductor device according to claim 11, before (c), electrical characteristics of the first semiconductor chip being examined.

26. The method to manufacture a semiconductor device according to claim 11, the first semiconductor chip having an outer configuration larger than an outer configuration of the second semiconductor chip.
